(19) United States
(12) Patent Application Publication
(10) Pub. No.: US 2007/0024377 A1
(43) Pub. Date: Feb. 1, 2007

(54) Impedance matching techiques for multi-band or wideband RF amplifiers and associated amplifier designs

(76) Inventors: Xuezhen Wang, Chandler, AZ (US); Noshir B. Dubash, Chandler, AZ (US); Douglas W. Schucker, Gilbert, AZ (US)

Correspondence Address: MOTOROLA, INC., 1303 EAST ALGONQUIN ROAD, IL01/3RD, SCHAUMBURG, IL, 60196, US

(21) Appl. No.: 11/191,591

(22) Filed: Jul. 28, 2005

(51) Int. Cl. H03F 3/191

(52) U.S. Cl. 330/305

(57) ABSTRACT

Multi-band or wideband impedance matching in RF amplifiers is disclosed, using variable negative feedback. The feedback is provided by variable impedance connected between the input and output terminals of an inverting amplifier, which may be single-ended, or differential. The variable impedance is used in conjunction with a fixed input impedance matching network to tune the variable impedance to different frequencies. The variable impedance feedback can also be used for gain control, and has the added benefit of stabilizing the amplifier. Both multi-band and wideband amplification can be optimized through the use of the disclosed circuitry and techniques. Use of an output impedance matching network in conjunction with the RF amplifier is optional.

### FIELD OF THE INVENTION

This invention relates to a radio frequency (RF) amplifier for use in a mobile positioning and communications devices.

### BACKGROUND

The field of wireless communications is rapidly changing, and customers continue to demand increased performance and features from their wireless communication devices (e.g., cellular phones, PDAs, computers, GPS receivers, etc.). Some features require the wireless devices to receive and transmit in different frequency bands. For example, a quad-band GSM phone with GPS and Bluetooth capability would need to communicate at 6 different frequency bands: four GSM bands (900, 1800, 1900 and 850 MHz); Bluetooth (2.4 GHz); and GPS (1575 MHz). Other mobile bands include 802.11a/b/g (2.4 GHz and 5-6 GHz); PCS (1850 and 1900 MHz); future civilian GPS (1228 MHz and 1176 MHz); and future Galileo (1176, 1207, 1279, and 1575 MHz). Note that these frequencies are actually a band or range of frequencies centered at the values specified above. Each of these frequency bands has a different bandwidth, or range of frequencies, and each is governed by different standards and specifications that need to be met by the wireless device.

Traditionally, and referring to FIG. 1, each band in a receiver would require its own RF front-end circuitry 200, consisting of an antenna 202, a filter 204, a RF amplifier 206, and mixer 208. (For more details, see T. Lee, “The Design of CMOS Radio-frequency Integrated Circuits,” Cambridge University Press (1998), which is hereby incorporated by reference). Additionally, each RF component in the circuitry 200 was optimized and impedance matched for a single frequency band. Thus, parallel implementations of the circuitry 200 were employed for each band. Since such parallel implementations increase the size, cost, and power-consumption of the wireless device, there is a strong incentive to make the RF front-end circuitry 200 operable at multiple frequencies. This disclosure focuses primarily on multi-band enablement of the RF amplifier 206, sometimes also referred to as the low-noise amplifier or LNA.

The primary and most challenging task in designing a multi-band RF amplifier is matching the input and output impedances of the amplifier at multiple frequencies. Any impedance mismatches result in a loss of the received signal, and also degrades the gain and noise performance of the amplifier, which determines the receiver's overall sensitivity. The capacitive and inductive parasitics present in the transistors, pads, connections, ESD circuitry, and packaging of the amplifier can drastically alter the RF impedances, and impedance matching must take all these effects into account. It is therefore challenging to design a high performance multi-band RF amplifier that is also a low-power, low-cost, and compact integrated solution.

Conventional dual band receiver architectures are illustrated in FIGS. 2A and 2B. In FIG. 2A, a single RF amplifier is used, but one of two different impedance matching circuits 210a or 210b are chosen depending on which band is active. FIG. 2B not only switches between the impedance matching circuits 210a and 210b, but also switches between two amplifiers 206a and 206b as well, each of which is tailored for optimal performance at the two bands of interest. The prior art generally uses one of these two basic techniques. U.S. Patent Publication No. 2004/0130392 provides two differential voltage-to-current converting circuits used in dual band amplifier. However, the drawback of this design is that two amplifiers are switched between dual bands, such as is shown in FIG. 2B, which consumes additional area and power. In U.S. Pat. No. 6,134,427, two diodes serve to vary the resonant frequency by selectively removing the series-connected inductor and capacitor from the circuit under the control of a signal generated by the controller. However, in this design, two input matching networks are provided for the two different bands, such as is shown in FIG. 2A. U.S. Pat. No. 6,882,223 is similar in that it proposes a multi-band low noise amplifier that requires two separate input matching networks for different bands, similar again to the scheme shown in FIG. 2A.

Other approaches also suffer from drawbacks. In U.S. Pat. No. 5,995,814, the input matching network utilizes a single set of elements to provide two narrowband matches in two distinct frequency bands. However, the single-ended amplifier illustrated in this reference requires two additional inductors and capacitors. This is an expensive solution regardless of whether it is implemented as an integrated or discrete solution: if integrated, a large amount of silicon area is required to fabricate the spiral inductors; if discrete, extra board space and component costs are incurred. U.S. Pat. No. 6,674,337 is similarly not optimal as it uses additional passive components (inductors and capacitors) to enable dual-band input and output matching, an approach which furthermore is not extendible to additional bands.

Another feature that is desirable in an RF amplifier is gain control. Gain control allows the amplifier gain to be reduced electrically if an active antenna is used, or in the presence of jammers that would saturate the front-end. However, it appears that there are no multi-band amplifier designs described in prior art which include gain control.

In short, improved impedance matching solutions are needed for the design of multi-band RF amplifiers that provide low power consumption, good performance, minimal hardware and cost, and gain control features. Such solutions are disclosed herein.

### SUMMARY

Multi-band or wideband impedance matching in RF amplifiers is disclosed, using variable negative feedback. The feedback is provided by variable impedance connected between the input and output terminals of an inverting amplifier, which may be single-ended, or differential. The variable impedance is used in conjunction with a fixed input impedance matching network to tune the variable impedance to different frequencies. The variable impedance feedback can also be used for gain control, and has the added benefit of stabilizing the amplifier. Both multi-band and wideband amplification can be optimized through the use of the disclosed circuitry and techniques. Use of an output impedance matching network in conjunction with the RF amplifier is optional.

### BRIEF DESCRIPTION OF THE DRAWINGS

Embodiments of the inventive aspects of this disclosure will be best understood with reference to the following detailed description, when read in conjunction with the accompanying drawings, in which:

FIG. 1 shows the essential front-end RF components of a typical receiver.

FIG. 2A shows a prior art method of switching between different impedance matching networks.

FIG. 2B shows another prior art method of switching between two RF amplifiers.

FIG. 3A illustrates the proposed method of variable negative feedback for use with a single-ended RF amplifier.

FIG. 3B illustrates the proposed method of variable negative feedback for use with a differential RF amplifier.

FIG. 4 shows on-chip implementations of the variable impedance.

FIG. 5 shows a generalized differential cascode amplifier with variable negative feedback in accordance with an embodiment of the invention.

FIG. 6 shows an NMOS implementation of the amplifier of FIG. 5.

FIG. 7 shows a psuedo-wideband amplifier with gain control in accordance with an embodiment of the invention.

FIG. 8 shows a dual-band dual-gain RF amplifier in accordance with an embodiment of the invention.

FIG. 9 shows an off-chip input impedance matching circuit which can be used for the amplifiers of FIGS. 5-8 or 10.

FIG. 10 shows a tri-band tri-gain RF amplifier in accordance with an embodiment of the invention.

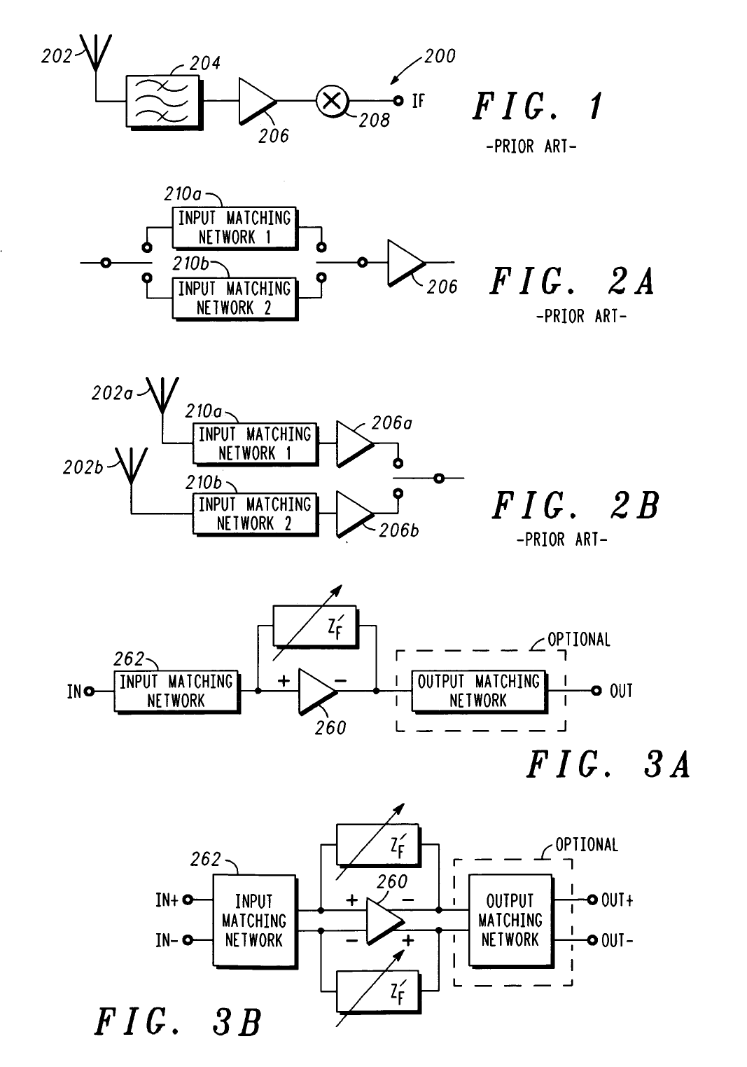

### DETAILED DESCRIPTION

As noted, a method for multi-band or wideband impedance matching in RF amplifiers is disclosed, using variable negative feedback. The feedback is provided by variable impedance, Z′_{F}, connected between the input and output terminals of an inverting amplifier 260, which may be single-ended (FIG. 3A) or differential (FIG. 3B). The variable impedance is preferably used in conjunction with a fixed input impedance matching network 262 to tune the variable impedance Z′_{F} to different frequencies. The variable impedance feedback can also be used for gain control, and has the added benefit of stabilizing the amplifier. Both multi-band and wideband amplification can be optimized through the use of the disclosed circuitry and techniques. Use of an output impedance matching network in conjunction with the RF amplifier is optional.

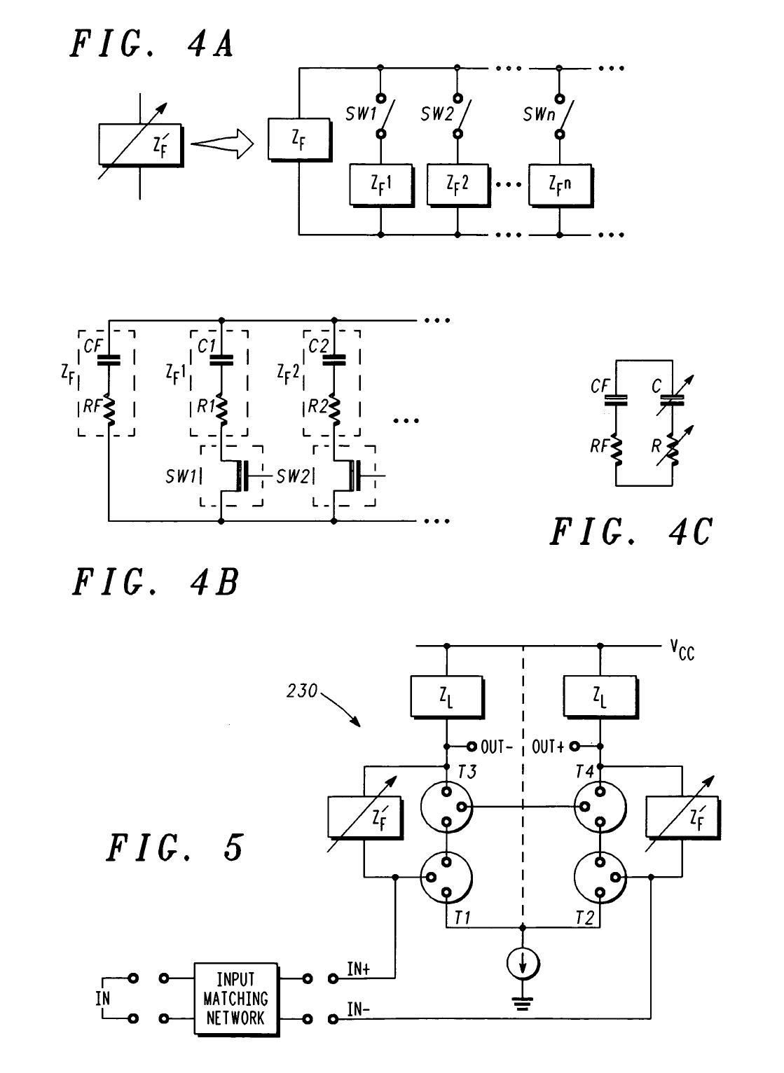

The variable impedance, Z′_{F}, may be implemented using a fixed impedance Z_{F} with additional impedances Z_{F1}, Z_{F2}, etc., that are connected parallel with Z_{F} via switches SW₁, SW₂, etc., as shown in FIG. 4A. Each impedance Z_{FX} may be implemented on chip as a capacitor, or a capacitor-resistor series combination, while the switches SW_{X} can be implemented on chip using Field Effect Transistors (FETs) as shown in FIG. 4B. These switches can be easily controlled by digital signals generated by the software or firmware driving the wireless device in which the circuitry is incorporated. If continuously tunable impedance is desired, it can be implemented on chip in various ways using a varactor and/or variable resistor, as shown in FIG. 4C.

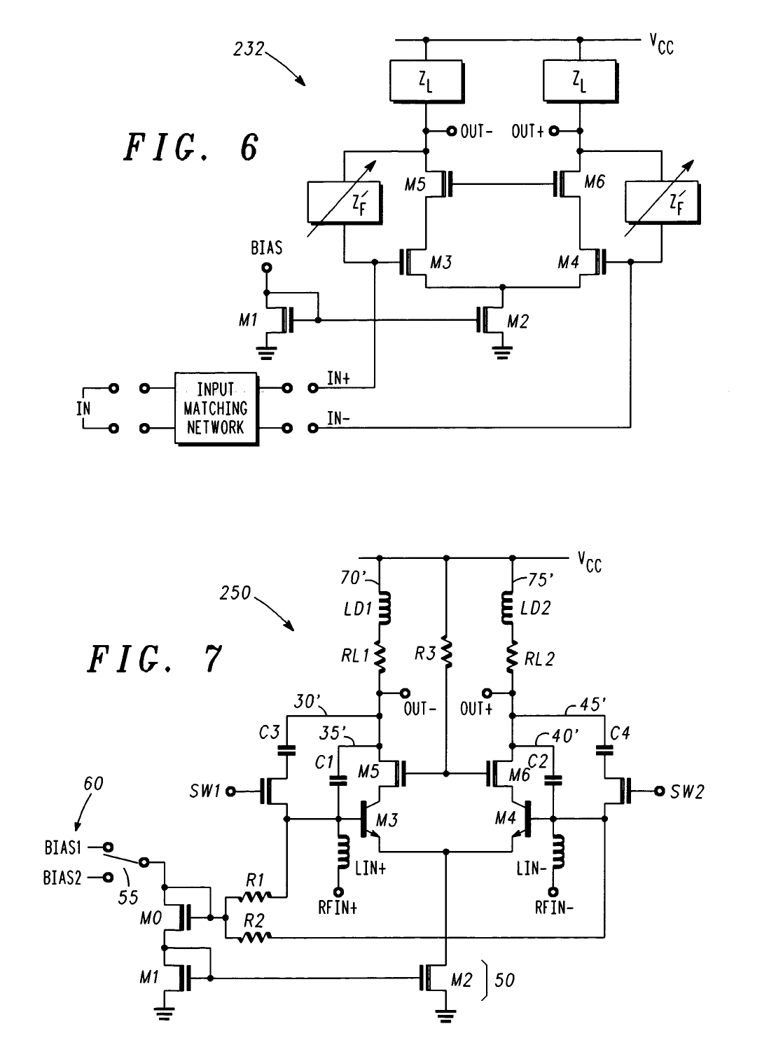

An example of an RF amplifier 230 benefiting from use of the variable impedance Z′_{F} feedback in accordance with an embodiment of the invention is shown in general form in FIG. 5. Although the RF amplifier 230 may be implemented in a number of different ways, a cascode architecture is preferred, which is well suited to low-noise integrated circuit designs. Consistent with the general cascode architecture of FIG. 5, transistors T₁-T₄ can be any 3-terminal transistors, although the most often used in RF integrated circuit designs are bipolar or NMOS devices. For low-noise amplifiers Z_{L} is usually implemented on chip as a spiral inductor. FIG. 6 depicts an NMOS implementation of the RF amplifier 232 with variable impedance Z′_{F}.

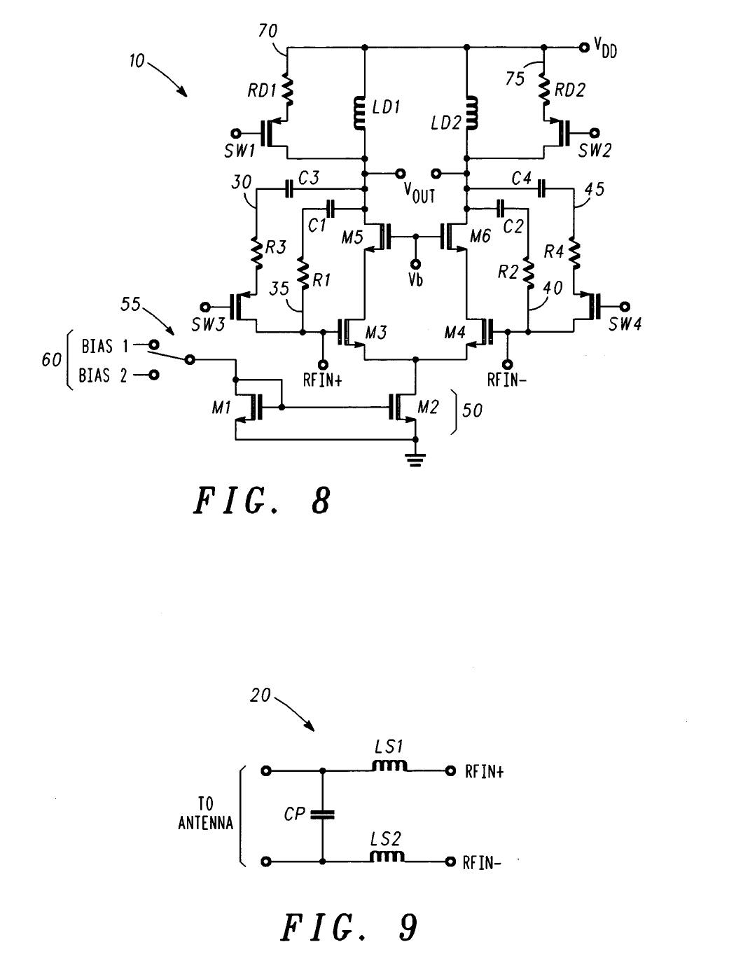

FIG. 8 shows in further detail a non-generalized first embodiment of an RF amplifier 10 for a wireless receiver utilizing variable impedance feedback. The RF amplifier 10 operates at two different frequency bands, with each band being operable at high gain or low gain. In the low gain mode, The RF amplifier 10 consumes less current, which is desirable given the limited battery power source of a typical wireless device. Although shown as implemented using Field Effect Transistors (FETs), one skilled in the art will recognize that the RF amplifier 10 can be implemented using bipolar transistors, or combinations of bipolar and FET transistors. In a preferred embodiment, the RF amplifier 10 can be configured on a single printed circuit board or integrated circuit chip. Because transistors are used as differential pairs, integrated CMOS or BiCMOS technologies are good candidates for actual implementation of the circuit.

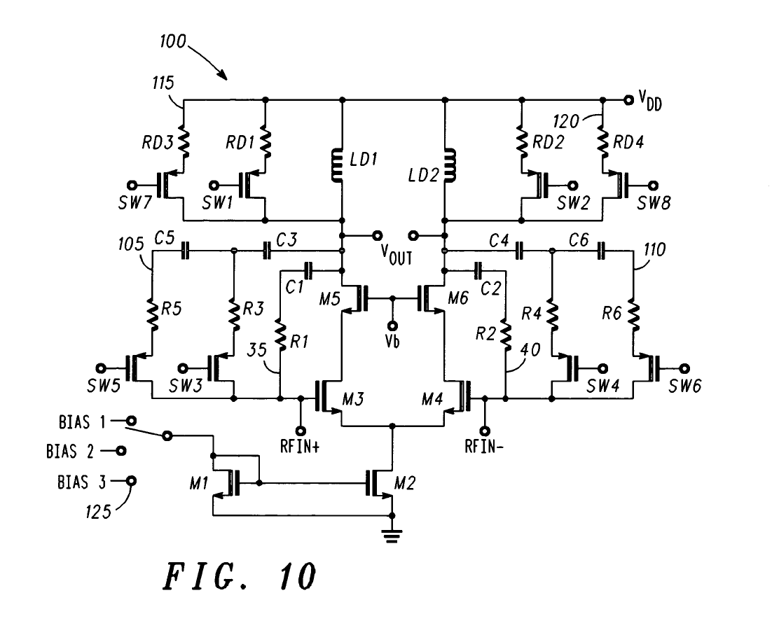

RF amplifier 10, as noted earlier, uses a differential cascode structure with an inductive load (LD1, LD2). Differential input signals RFIN+ and RFIN− are taken from the antenna or RF filter and applied to the voltage inputs of the RF input transistors M3 and M4. A current mirror source 50 is provided for the differential pair. A fixed off-chip input matching circuit 20 (FIG. 9) is provided for both frequencies or bands, and is coupled to the differential inputs RFIN+ and RFIN−.

The variable impedances discussed earlier between the input and output of RF amplifier 10 comprise, in this embodiment, four feedback paths 30, 35, 40, 45, which each comprise a series-connected resistor and capacitor (see generally FIG. 4B). Specifically, these paths are connected between the gates of the RF input transistors M3, M4, and the drains of the cascode transistors M5, M6. The gates of the cascode transistors M5, M6 are connected to a reference bias, Vb, which might for example constitute the operating voltage (e.g., Vdd) of the circuit 10.

Two of the feedback paths (30, 45) are controlled by two switches, SW3 and SW4. At a first frequency band (Band 1), switches SW 3 and SW4 are off, which effectively takes feedback paths 30 and 45 out of the circuit. At a second, lower frequency band (Band 2), switches SW3 and SW4 are turned on, essentially connecting paths 30 and 35, and 40 and 45, in parallel (i.e., a switched feedback technique), hence resulting in the variable impedance discussed earlier. Either way, through either of the pairs of paths to the RF input transistors M3, M4 (i.e., paths 35 and 30, or 30 and 45), the output voltage is fed to the input to provide feedback. Thus, the RF amplifier 10 is adjustable depending on which of the two frequencies are being detected, or are desired to be detected, by the receiver at any given moment.

Although the physics here should be understandable by those of skill in the art, it is worth noting by way of clarification that most RF components, including antennas and filters, which may be connected to the input of this amplifier, are matched to 50 ohms. Thus, to transfer maximum RF power from the antenna or filter to the amplifier, the amplifier input (RFin) must also appear to be 50 ohms with no imaginary or reactive component to the impedance. However, the transistors of the amplifier (e.g., M3, M4) have real impedance components that differ from 50 ohms, and additionally comprise input capacitances which comprise reactive components in addition to the real parts of the impedance. In sum, this makes the input impedance of the amplifier appear different from 50 ohms. To match or transform the input impedance, a fixed external inductor and capacitor (i.e., from fixed off-chip input matching circuit 20 (FIG. 9)) is used to “tune out” the input capacitance of the transistors and to transform the impedance to 50 ohms. Because these tuning components involve reactive components (inductors and capacitors), the first-order matching or tuning will only be optimized for a given frequency. Accordingly, if other feedback capacitors (e.g., capacitors C3 and C4) are added to the same input, this changes the optimal frequency of the match because it adds additional reactance to the impedance.

Accordingly, through the use of this disclosed architecture, the RF amplifier can be tuned for the two frequency bands of interest, while at the same time allowing for the use of a fixed off-chip input matching circuit 20 (FIG. 9) that works for both bands. Moreover, the number of components used in the design is lessened compared to other dual band circuits, and consumes less board/chip area and power.

As noted earlier, another feature of the RF amplifier 10 is its dual-gain nature for each of the frequency bands. Providing dual gain in the RF amplifier 10 of FIG. 8 is accomplished by two concurrent mechanisms: switching the supply current and switching the load resistance. First, as regards switching the supply currents, a current source 50 is coupleable to one of two different current biases 60 (Bias 1 and Bias 2) through a switch 55, with I_{bias1} being lower than I_{bias2}. The current source 50 employs a current mirror, which assists in improving the common mode rejection ratio of the RF amplifier 10. As there are many methods for designing bias currents in the art, details of the generation of current biases 60 are not provided. Again, which current bias 60 is chosen will depend on the amplitude of the RF signal received at the antenna, and how much amplification will be required, or other criteria determined by the application and receiver.

Second, and concurrent with switching of the current biases 60, the load resistance on the RF amplifier 10 is adjusted depending on the bias level (i.e., gain level) to be utilized. This load is adjusted using resistance paths 70 and 75, each of which provides a series connection between a switch (SW1 or SW2) and a load resistor (RD1 or RD2). When high gain is desired (Bias 2), SW1 and SW2 are off, effectively removing the load resistors RD1, RD2 from the circuit. When lower gain is desired (Bias 1), SW1 and SW2 are on, coupling the load resistors in parallel with the load inductors LD1, LD2. The parallel load resistors RD1, RD2 assist in input impedance matching that would otherwise be degraded by changing the bias current.

The level of gain to be used may be a determination made automatically by the wireless device, on the basis of an automatic gain control (AGC) loop. As applied here, such gain control circuitry can be used to control switches SW1, SW2, and 55. Alternatively, the gain can be selected manually by the user of the wireless device to control these switches.

To summarize, the RF amplifier 10 of FIG. 8 is both dual band and dual gain as controlled by switches SW1-4 and 55 (I_{bias}). The following table summarizes the setting for each of these switches for the various operating conditions:

| Band | Gain | SW3 and SW4 | SW1 and SW2 | I_{bias} |
|---|---|---|---|---|
| high (Band 1) | high | off | off | high (I_{bias2}) |
| high (Band 1) | low | off | on | low (I_{bias1}) |
| low (Band 2) | high | on | off | high (I_{bias2}) |
| low (Band 2) | low | on | on | low (I_{bias1}) |

Thus, the RF amplifier 10 will amplify two bands and at two gain levels, all with optimized input impedance matching and power savings. As one skilled in the art will understand, the values for the various inductive, capacitive, and resistive components in FIGS. 8 and 9 can and will vary in accordance with user preferences, such as which two frequency bands are to be used, what the two gain values will be, etc. Moreover, it is not particularly useful to disclose any particular set of values, because such values in reality depend on the foundry or manufacturer's detailed device models and the RF amplifier 10's operating environment (e.g., packaging and layout considerations, which can add parasitic capacitance and inductances not reflected in the circuit of FIG. 8). In short, a working circuit will require some degree of normal design and optimization to arrive at suitable component values, but is well within the abilities of one skilled in the art of RF amplifier design.

The concepts as introduced with respect to the RF amplifier 10 of FIG. 8 can be extended to the design of an RF amplifier that is multi-band/dual-gain, dual-band/multi gain, or even multi-band/multi-gain. A multi-band/multi-gain amplifier 100 is shown in FIG. 10. As shown, the RF amplifier 100 is a tri-band/tri-gain amplifier, a result which is achieved by adding additional feedback paths 105, 110, additional load resistance paths 115, 120, and an additional current bias 125 (I_{bias3}) to the circuit of FIG. 8.

To bias the RF amplifier to one of its three operative frequency bands, either no switches are opened (Band 1; highest frequency), or switches SW3 and SW4 are opened (Band 2; middle frequency), or switches SW3-SW6 are opened (Band 3; lowest frequency). Likewise, to choose a gain setting, switch 55 is routed to the appropriate current bias (Ibias1=lowest gain; Ibias2=medium gain; Ibias3=highest gain), and switches SW1, SW2, SW7, SW8 are opened or closed in various manners to assist in input impedance matching necessitated by the change in the bias current: SW1=SW2=SW7=SW8=off (highest gain); SW1=SW2=on, SW7=SW9=off (medium gain); SW1=SW2=SW7=SW8=on (lowest gain).

In short, the basic circuit structure of FIG. 8 can be manipulated to tailor the number of band and gains at which the RF amplifier operates. That being said however, the dual-band/dual-gain RF amplifier of FIG. 8 will be the simplest to engineer and model. In this regard, one skilled in the art will recognize that the addition of extra components to increase the number of bands and/or gains for the RF amplifier will add increasing complex parasitics to the circuit. Therefore, while the basic circuit of FIG. 8 is scalable to provide multi-band and/or multi-gain performance as shown in FIG. 10 for example, engineering will become increasing more complex, although still within the abilities of one skilled in the art.

In another detailed embodiment, a pseudo-wideband RF amplifier 250 design is presented, as shown in FIG. 7. In this design, the two frequency bands to which the RF amplifier 250 are tuned are close enough (e.g., GPS L1 and L2 bands at 1227 MHz and 1575 MHz), and the performance requirements are flexible enough, so that a wideband amplifier design is possible. As a result, a frequency select switch, i.e., switched SW3 and SW4 of FIG. 8, are not necessary. Instead, switches in the feedback paths (SW1 and SW2 in FIG. 7) are used for gain control. In the low gain mode, the RF amplifier 250 consumes less current, which is useful for low power wireless applications. The RF amplifier 250 in this embodiment is implemented using BiCMOS technology.

The RF amplifier 250 again preferably uses a differential cascode structure, and as shown in FIG. 7 comprises a series combination of inductive (LD1, LD2) and resistive (RL1, RL2) loads, i.e., paths 70′ and 75′. Differential input signals RFIN+ and RFIN− are taken from the antenna or RF filter and applied to the voltage inputs of the RF input transistors M3 and M4, with a current mirror source (i.e., M1 and M2) provided for the differential pair. In this embodiment, an on-chip input matching circuit is used, which is comprised of two on-chip inductors LIN+ and LIN−. Thus, note that in this particular design, by taking advantage of the capacitance of the feedback path capacitors and the RF input transistors M3 and M4, no extra input matching capacitor (such as Cp shown in off-chip input matching circuit 20 of FIG. 9) is needed.

As shown, four feedback paths 30′, 35′, 40′, 45′, each comprising a capacitor, are constructed between the bases of the RF input transistors M3, M4, and the drains of the cascode transistors M5, M6. The gates of the cascode transistors M5, M6 are connected to a reference bias, Vb, which again may constitute the operating voltage (e.g., Vdd) of the RF amplifier 250.

Through the use of this disclosed architecture, the RF amplifier can be used with a wide frequency band of interest, while at the same time allowing the use of a fixed on-chip input matching circuit (e.g., inductors LIN+, LIN−) that work to match across the wideband. The number of components used in this design is less compared to other dual band circuits, and hence consumes less board/chip area and power.

As noted earlier, another feature of the RF amplifier 250 is its dual-gain nature across the wideband. Providing dual gain in the RF amplifier 250 of FIG. 7 is accomplished by two concurrent mechanisms: switching the supply current and switching the feedback capacitance. First, as regards switching the supply currents, and as is similar to the embodiment of FIG. 8, a current source 50 is coupleable to one of two different current biases 60 (Bias 1 and Bias 2) through a switch 55, with I_{bias1}, being lower than I_{bias2}. The current source 50 employs a current mirror, which assists in improving the common mode rejection ratio of the RF amplifier 250. As there are many methods for designing a bias current in the art, details of the generation of the current biases 60 are not provided. Again, which current bias 60 is chosen will depend on the amplitude of the RF signal received at the antenna, and how much amplification will be required, or other criteria determined by the application and receiver.

Second, two of the feedback paths (30′, 45′) are controlled by two switches, SW1 and SW2. Concurrent with switching of the current biases 60, the feedback capacitance on the RF amplifier 250 is adjusted depending on the bias level (i.e., gain level) to be utilized. This is adjusted using paths 30′ and 45′, each of which provides a series connection between a switches SW1 and SW2 and feedback capacitors C3 and C4. When high gain is desired (Bias 2), SW1 and SW2 are off, effectively removing the feedback capacitors C3, C4 from the circuit. When lower gain is desired (Bias 1), SW1 and SW2 are on, coupling the capacitors in parallel with feedback capacitors C1, C2. The parallel feedback capacitors C3, C4 assist in input impedance matching that would otherwise be degraded by changing the bias current.

The level of gain to be used may be a determination made automatically by the wireless device, on the basis of an automatic gain control (AGC) loop. As applied here, such gain control circuitry can be used to control switches SW1, SW2, and 55. Alternatively, the gain can be selected manually by the user of the wireless device to control these switches.

To summarize, the RF amplifier 250 of FIG. 7 is both wideband and dual gain as controlled by switches SW1-2 and 55 (I_{bias}). The following table summarizes the setting for each of these switches for the various operating conditions:

| Band | Gain | SW1 and SW2 | I_{bias} |
|---|---|---|---|
| Band 1 & 2 | high | off | high (I_{bias2)} |
| Band 1 & 2 | low | on | low (I_{bias1)} |

Thus, the RF amplifier 250 will amplify a wide band of frequencies at two gain levels, with optimized input impedance matching (preferably on chip impedance matching) and power savings. As one skilled in the art will understand, the values for the various inductive, capacitive, and resistive components in FIG. 7 can and will vary in accordance with user preferences, such as which two frequency bands are to be used, what the two gain values will be, etc. Moreover, it is not particularly useful to disclose any particular set of values, because such values in reality depend on the foundry or manufacturer's detailed device models and the circuit 250's operating environment (e.g., packaging and layout considerations, which can add parasitic capacitance and inductances not reflected in the circuit of FIG. 7). In short, a working circuit will require some degree of normal design and optimization to arrive at suitable component values, but is well within the abilities of one skilled in the art of RF amplifier design.

An output matching network is optional depending on the applications at hand. Integrated implementations are most commonly used in modem wireless receiver circuits due to reduced size and cost. If the RF amplifier is integrated on chip and directly followed by an integrated mixer, one only needs to adjust the load inductors of the RF amplifier to match the mixer input capacitance. In other words, additional output matching circuitry is not required. For discrete implementations, or when the RF amplifier output needs to match to 50 ohms for a single-ended case or 100 ohms for a differential case, an output matching network is preferably used. The output matching network can be either single-ended or differential depending on the RF amplifier configuration. Output matching is well known to those of skill in the art of RF amplifier design, and well within such persons' abilities.

It should be understood that the inventive concepts disclosed herein are capable of many modifications. To the extent such modifications fall within the scope of the appended claims and their equivalents, they are intended to be covered by this patent.

What is claimed is:

1. A circuit for multi-band or wideband impedance matching in a radio-frequency amplifier, comprising:
an amplifier stage comprising at least one input terminal and one output terminal; and
at least one feedback path between the input terminal and the output terminal, wherein the feedback path comprises a variable impedance used to tune the amplifier to different multi-band or wideband frequencies.

2. The circuit of claim 1, wherein the variable feedback path is between the input terminal and the output terminal of an inverting amplifier stage.

3. The circuit of claim 1, wherein the amplifier stage comprises a cascode amplifier stage.

4. The circuit of claim 1, wherein the variable impedance comprises a first fixed impedance in parallel with at least one other fixed impedance selectable by a switch.

5. The circuit of claim 4, wherein each of the first fixed impedance and the at least one other fixed impedance comprise a serially-connected resistor and capacitor.

6. The circuit of claim 4, wherein each of the first fixed impedance and the at least one other fixed impedance comprises a capacitor.

7. The circuit of claim 1, wherein the amplifier stage comprises an inductive load.

8. The circuit of claim 7, wherein the impedance of the load is variable in accordance with a gain of the amplifier.

9. The circuit of claim 7, further comprising a current source coupled to the amplifier stage, wherein the current source is variable in accordance with the gain of the amplifier.

10. The circuit of claim 1, wherein the amplifier stage comprises two differential input terminal and two differential output terminals; and two feedback paths between pairs of the input and output terminals, wherein the feedback paths comprise a variable impedance used to tune the amplifier to different of the multi-band or wideband frequencies.

11. The circuit of claim 1, wherein the circuit is formed on an integrated circuit, and further comprising a single fixed input matching circuit which may be integrated or off-chip.

12. A circuit for adjusting a gain of multi-band or wideband radio-frequency amplifier, comprising:
an amplifier stage comprising at least one input terminal and one output terminal;
at least one feedback path between the input terminal and the output terminal, wherein the feedback path comprises a variable impedance matched to the gain of the amplifier at multi-band or wideband frequencies; and
a current source coupled to the amplifier stage, wherein the current source is variable in accordance with the gain of the amplifier.

13. The circuit of claim 12, wherein the variable feedback path is between the input terminal and the output terminal of an inverting amplifier stage.

14. The circuit of claim 12, wherein the amplifier stage comprises a cascode amplifier stage.

15. The circuit of claim 12, wherein the variable impedance comprises a first fixed impedance in parallel with at least one other fixed impedance selectable by a switch.

16. The circuit of claim 15, wherein each of the first fixed impedance and the at least one other fixed impedance comprises a capacitor.

17. The circuit of claim 12, wherein the amplifier stage comprises an inductive load.

18. The circuit of claim 12, wherein the amplifier stage comprises two differential input terminal and two differential output terminals; and two feedback paths between pairs of the input and output terminals, wherein the feedback paths comprise a variable impedance matched to the gain of the amplifier at the multi-band or wideband frequencies.

19. The circuit of claim 12, wherein the current source comprises a current mirror.

20. The circuit of claim 12, wherein the circuit is formed on an integrated circuit, and further comprising a single fixed input matching circuit which may be integrated or off-chip.
